(19) United States
(12) Patent Application Publication
(10) Pub. No.: US 2025/0340997 A1
(43) Pub. Date: Nov. 6, 2025

(54) METHOD FOR PREPARING A SUBSTRATE COATED WITH AN INTERMEDIATE LAYER AND A DIAMOND LAYER

(71) Applicants: CARBONCOMPETENCE GMBH, Wattens (AT); YG-1 CO., LTD., lncheon (KR)

(72) Inventors: Doris STEINMÜLLER-NETHL, Aldrans (AT); Detlef STEINMÜLLER, Aldrans (AT)

(73) Assignees: CARBONCOMPETENCE GMBH, Wattens (AT); YG-1 CO., LTD., lncheon (KR)

(21) Appl. No.: 19/099,476

(22) PCT Filed: Sep. 5, 2022
(86) PCT No.: PCT/AT2022/060304

§ 371 Date: Jan. 29, 2025

(51) Int. Cl. C23C 28/04; C23C 14/06; C23C 16/02; C23C 16/27; C23C 16/40; C23C 16/455

(52) U.S. Cl. CPC C23C 28/044; C23C 14/0647; C23C 14/0652; C23C 16/0227; C23C 16/0272; C23C 16/27; C23C 16/403; C23C 16/45536

(57) ABSTRACT

The present invention relates to a method for preparing a substrate coated with an intermediate layer and a diamond layer, comprising the following steps: (a) roughening a surface of the substrate with an etchant, (b) coating the roughened surface of the substrate with an intermediate layer, (c) nucleating a surface of the intermediate layer, and (d) coating the nucleated surface of the intermediate layer with a diamond layer by means of a chemical vapor deposition (CVD) process, wherein the intermediate layer comprises aluminum oxide (Al₂O₃) and/or AlCrXN, with Al being aluminum, Cr being chromium, X being a metalloid, preferably silicon (Si) or boron (B), and N being nitrogen. The present invention is further directed to a substrate with an intermediate layer and a diamond layer obtainable by said method.

The present invention relates to a method for preparing a substrate coated with an intermediate layer and a diamond layer, and to a substrate coated with an intermediate layer and a diamond layer obtainable by said method.

Diamond-coated tools have a high hardness, good wear resistance, low friction coefficient, good thermal conductivity and a low thermal expansion coefficient, which results in an excellent cutting performance. The application of a diamond layer is commonly performed via chemical vapor deposition (CVD). However, the direct application of a diamond layer onto certain substrates is difficult and the resulting diamond layer may not adhere well to the substrate. Especially the deposition of a diamond layer onto a cemented carbide is challenging. A cemented carbide is a composite material comprising hard particles and a binder phase binding the hard particles together, with the binder phase usually comprising any of cobalt, nickel and iron. When applying a diamond layer onto a cemented carbide, the binder phase can negatively affect nucleation and diamond growth and can promote the formation of non-diamond carbon substances, which in turn can deteriorate the quality of the diamond layer and its adhesion to the substrate.

Several methods are known in the art to improve the adhesion of a diamond layer to a substrate, particularly a cemented carbide. Fundamentally, the binder phase (in most cases cobalt) must be passivated. One method is the depletion of the binder phase from a surface-near region of the cemented carbide by means of etching prior to the application of a diamond layer. However, the removal of the binder phase can lead to embrittlement and reduction of the fracture toughness, which is likely to result in breakage. According to another method, an intermediate layer with a good adhesion to both the cemented carbide and the diamond layer can be deposited onto a surface of the cemented carbide. The intermediate layer can act as diffusion barrier for the binder phase and can compensate for differences in thermal and/or mechanical stress between the substrate and the diamond layer.

DE 44 34 428 A1 discloses a composite material consisting of a body based on a hard metal, cermet, ceramic or steel, onto which an intermediate layer and a polycrystalline diamond layer are applied. The intermediate layer comprises a predominantly tetrahedrally bonded, amorphous carbon-containing layer.

In EP 2 558 610 B1, a method for forming a coating layer comprising an intermediate layer and a diamond layer using PVD is disclosed. Si and C are essential components of the formed SiₓC_{1-x-y-z}N_{y}M_{z} intermediate layer and M is one or more elements selected from Ti, Zr, Hf, V, Nb, Ta, Cr, Mo, W, Y, B, Al and Ru (wherein 0.4≤x≤0.6, 0≤y≤0.1, and 0≤z≤0.2).

WO 2018/112909 A1 provides a method for pre-treatment of cemented carbide prior to the application of a diamond coating wherein etching of the binder phase is followed by coating the cemented carbide with a coating comprising a base layer (diamond layer or cubic boron nitride layer), an intermediate layer and a top layer (tetrahedral amorphous carbon film layer). The intermediate layer includes a metallic transition layer and a core layer made of metal nitride, metal carbonate or metal borate.

CN 114134504 A reports the etching of tungsten carbide (WC) grains of a cemented carbide tool with Murakami reagent and the removal of a binder phase with an acid solution (e.g. a mixture of sulfuric acid and hydrogen peroxide), followed by immersing the cemented carbide tool into a mixed solution of copper sulfate and chromium sulfate. Cobalt present in surface-near regions of the cemented carbide tool is partially replaced, and a cemented carbide tool with a subsurface layer of cobalt covered with a copper-chromium layer is obtained. The treated cemented carbide tool can then be nucleated in a diamond powder suspension before starting CVD diamond growth.

U.S. Pat. No. 6,214,247 B1 relates to a method for removing a portion of a binder phase from the surface of a substrate (e.g. a cemented carbide, a cermet or a nitride) by means of an etchant gas to form voids in the surface. A coating comprising materials selected from the group consisting of TiC, TiN, TiCN, diamond, Al₂O₃, TiAlN, HfN, HfCN, HfC, ZrN, ZrC, ZrCN, Cr₃C₂, CrN and CrCN is subsequently deposited within these voids to increase the wear resistance of the substrate (e.g. metal cutting inserts, dies, punches).

US 2003/129456 A1 focuses on a cemented carbide comprising a hard phase component which comprises a tungsten carbide and at least one selected from carbides, nitrides and carbonitrides of metals of the groups 4a, 5a and 6a in the periodic table. The cemented carbide can be coated with a layer comprising at least one of metal carbide, metal nitride, metal carbonitride, TiAlN, TiZrN, diamond-like carbon (DLC), diamond and Al₂O₃, with the metal being selected from the groups 4a, 5a and 6a in the periodic table.

EP 0 503 822 A2 relates to a hard material (e.g. cemented carbide) onto which an intermediate layer is applied, e.g. via CVD, PVD or sputtering. The intermediate layer is composed of materials capable of readily causing nucleation, such as silicon nitride-, silicon carbide- or Al₂O₃-containing materials. The surface of the intermediate layer coated onto the hard material is then roughened, e.g. by means of scratching or etching. This increases nucleation during a subsequent coating step to apply a diamond- and/or diamond-like carbon-coating layer.

US 2013/164557 A1 discloses a substrate coated with an intermediate layer in a PVD process. The intermediate layer has a metal portion that consists by more than 50 at % of W and/or Cr. Before the PVD process, the substrate can undergo a blasting treatment (e.g. by means of sand-blasting with hard material particles) to increase its roughness. After the PVD process, the applied intermediate layer can be roughened and subjected to a nucleation pretreatment with abrasive and/or diamond particles. A diamond layer is subsequently applied via CVD.

It is an object of the present invention to provide a substrate coated with an intermediate layer and a diamond layer, with the intermediate layer significantly reducing the diffusion of atoms and/or ions present in the substrate through the intermediate layer when applying the diamond layer.

This object is solved with (i) a method for preparing a substrate coated with an intermediate layer and a diamond layer, and (ii) a substrate coated with an intermediate layer and a diamond layer obtainable by said method, according to the claims.

The present invention relates to a method for preparing a substrate coated with an intermediate layer and a diamond layer, comprising the following steps:
(a) roughening a surface of the substrate with an etchant,
(b) coating the roughened surface of the substrate with an intermediate layer,
(c) nucleating a surface of the intermediate layer, and
(e) coating the nucleated surface of the intermediate layer with a diamond layer by means of a chemical vapor deposition (CVD) process,
wherein the intermediate layer comprises aluminum oxide (Al₂O₃) and/or AlCrXN, with Al being aluminum, Cr being chromium, X being a metalloid, preferably silicon (Si) or boron (B), and N being nitrogen.

The substrate used in the present invention can be selected from metals, such as iron, molybdenum, tungsten and alloys thereof (e.g. tungsten carbide), cemented carbides, steels (e.g. stainless steels, high speed steels), silicon nitride, or mixtures thereof. Various tools can be used as substrate, e.g. cutting tools (inserts, shank tools), punching tools, knives, wear parts like dies or moulds, and others. Accordingly, further disclosed is the use of the substrate coated with the intermediate layer and the diamond layer as a tool.

It was found in the present invention that using an intermediate layer that comprises Al₂O₃ and/or AlCrXN, particularly Al₂O₃, AlCrSiN, AlCrBN or a mixture thereof, provides an effective barrier to prevent the diffusion of atoms and/or ions present in the substrate, particularly a binder phase of a cemented carbide, through the intermediate layer during the application of a diamond layer in the CVD process, which could otherwise negatively affect nucleation and diamond growth. This, in turn, could hinder the formation of sp³-hybridized carbon and instead promote the formation of non-diamond carbon substances, which would significantly deteriorate the quality of the diamond layer.

In a preferred embodiment according to the present invention, the substrate is a cemented carbide (also referred to as carbide). The intermediate layer provides an excellent diffusion barrier for the binder phase present in a cemented carbide, which binder phase may otherwise negatively affect diamond growth at the interface and thus result in a weak adhesion. In the present invention, a high-quality diamond layer can be deposited onto the intermediate layer independent on the grade of cemented carbide as substrate. Particularly preferably, a cemented carbide comprising tungsten carbide as hard phase and cobalt as binder phase is used as substrate in the present invention. Various amounts of cobalt can be comprised in the cemented carbide substrate, for example from 3 to 12 wt %. Firstly, tungsten carbide has a high hardness, and secondly, it exhibits an excellent response to etching (particularly when using a Murakami reagent as etchant), such that the surface of the tungsten carbide can be well prepared for further treatment.

Preferably, the intermediate layer consists of AlCrSiN, AlCrBN or Al₂O₃, which all have an excellent high-temperature-stability in the diamond growth range up to 1,100° C. Further, the surface energy of AlCrSiN, AlCrBN and Al₂O₃ allows for a high nucleation density when subjected to nucleation, such that a closed diamond layer (i.e., a uniform layer, preferably without any holes or defects) can be deposited onto the nucleated surface of the intermediate layer. Also, AlCrSiN, AlCrBN and Al₂O₃ all show a good adhesion to the substrate and provide an excellent resistance to stress, such as thermal or mechanical stress, which in turn is favorable for the adhesion of the intermediate layer to the diamond layer. An intermediate layer comprising AlCrBN brings the advantage over an intermediate layer comprising AlCrSiN that not only a good passivation of the binder phase can be obtained, but that due to the crystal lattice of boron nitride (BN) being similar to that of diamond, internal stresses that can negatively impact the adhesion can be minimized.

Preferably, the Al₂O₃ used in the intermediate layer of the present invention is amorphous. The advantage of an amorphous Al₂O₃ layer is that it is more compact and denser than a crystalline structure of Al₂O₃, especially when deposited at a low temperature (e.g. below 300° C.), and thus, even a very thin layer can be deposited in a closed manner and without pores.

According to the present invention, a surface of the substrate is roughened with an etchant. A roughened surface is obtained herewith which can allow for a deeper ingrowth of the interlayer, e.g. due to enhanced mechanical bonding. Further, at least some of the binder phase present in a surface-near region of the substrate can be removed during etching, which increases the distance of the remaining binder phase to the subsequently applied diamond layer. This in turn reduces the diffusion of the binder phase, such as cobalt, during the application of the diamond layer and thus supports the generation of sp³-hybridized carbon, hereby improving the adhesion. The substrate can be immersed into the etchant to ensure a homogeneous etching of the whole surface. Prior to the etching step, the surface of the substrate can be mechanically pre-treated (e.g. by means of wet blasting, dry blasting, drag finishing) and/or cleaned (e.g. ultrasonically) by using typical cleaning solutions to remove undesired substances such as grinding lubricants, oil and residual contamination, in order to prepare the surface for the subsequent etching step, independent on the used substrate type (e.g. the carbide grade when the substrate is a cemented carbide). Preferably, the surface of the substrate is cleaned prior to etching. The etchant is preferably applied as an etching solution, i.e. a solution of the etchant in water, particularly demineralized water, with the concentration of the etchant preferably being in the range of 50 to 95 wt % (with respect to the total weight of the solution). This allows to apply a longer etching time without damaging the surface of the substrate, which in turn increases the roughness of the surface and thus the adhesion to the subsequently applied intermediate layer. Preferably, the surface of the substrate is etched for 30 sec to 5 min at 20 to 40° C. These conditions were found to prepare the surface of the substrate well for the subsequent coating step, such that a good adhesion to the intermediate layer can be obtained.

In a preferred embodiment of the present invention, the surface of the substrate is etched with a Murakami reagent. The Murakami reagent is an excellent etchant and well capable of roughening the surface of the substrate, such that the adhesion to the subsequently applied intermediate layer can be considerably enhanced. The Murakami reagent can comprise 1 part of potassium ferricyanide III, 1 part of potassium hydroxide and 10 parts of water (parts per weight). Instead of potassium hydroxide, sodium hydroxide can also be used. It was found in the present invention that the Murakami reagent is particularly suitable to etch tungsten carbide (WC), resulting in a surface with a high roughness, which allows for a good mechanical bonding to the subsequently applied intermediate layer, and thus a good adhesion. Accordingly, a Murakami reagent is particularly preferably used as etchant when tungsten carbide is comprised in the hard phase of the substrate. Preferably, the etching of the surface of the substrate with the Murakami reagent is performed at a temperature in the range of 20 to 40° C. for 30 sec to 5 min. When applying these conditions, the adhesion of the subsequently applied intermediate layer to the surface of the substrate can be significantly enhanced. In a particularly preferred embodiment, the etching is carried out for 3 min at 25° C.

Further preferably, the etching of the present invention is performed as a multi-step etching process. Thus, according to a preferred embodiment of the present invention, the etching with the Murakami reagent is followed by etching with an acid. As the Murakami reagent is alkaline, subsequent etching with an acid allows to remove components from the substrate that could not be etched and removed with the Murakami reagent. The combined surface treatment with the Murakami reagent and an acid results in an optimum preparation of the substrate surface for the subsequent coating with the intermediate layer. On the one hand, the surface of the substrate can be significantly roughened, which improves its adhesion to the intermediate layer by means of mechanical bonding. The resulting degree of surface roughness is such that a planar and uniform intermediate layer can be obtained upon coating the surface of the substrate in a subsequent step. On the other hand, the binder phase can be sufficiently removed from the surface-near region of the substrate, which leads to a significant reduction of diffusion of the binder phase during the application of a diamond layer via the CVD process.

When using a cemented carbide as substrate in the present invention, the acid is preferably an acid which is capable to act as etchant for the binder phase of the cemented carbide. As such, at least some of the binder phase present on the surface (for example due to a previous grinding step) and in a surface-near region of the cemented carbide can be removed upon etching. Depletion of the binder phase from said surface-near region can reduce the diffusion of the remaining binder phase of deeper regions of the cemented carbide towards and through the subsequently applied intermediate layer, such that a high-quality diamond layer can be deposited. In-between the etching steps, the surface can be cleaned, e.g. with water, preferably demineralized water. The etching of the substrate surface with the acid is preferably performed at a temperature in the range of 20 to 40° C. for 30 sec to 5 min. Applying these conditions was found to result in an excellent adhesion of the subsequently applied intermediate layer to the surface of the substrate. Several acids are suitable for use in the present invention, such as nitric acid (or a solution thereof), sulfuric acid (or a solution thereof), or a solution of peroxysulfuric acid (also known as Caro's acid). For example, several acids can be used in subsequent etching steps. Nitric acid is preferably used in the present invention because it can be handled easily and allows for an efficient etching. Furthermore, nitric acid is particularly suitable when using a cemented carbide as substrate, as it shows a good etching efficiency towards commonly used binder phases, especially cobalt. A particularly effective etching can be achieved when using a nitric acid solution in water, with a concentration of 50 to 60 wt % nitric acid (with respect to the total weight of the solution). In a preferred embodiment, the etching with nitric acid (57 wt % solution) is performed for 60 sec at 25° C.

It is particularly preferred in the present invention that the surface of the substrate is etched in a two-step etching process by etching with a Murakami reagent and an acid, preferably nitric acid. Preferably, the etching with Murakami reagent is performed in a first step and the etching with the acid is performed in a second step of the two-step etching process. Particularly preferably, the surface of the substrate is etched for 30 sec to 5 min with the Murakami reagent and 30 sec to 5 min with the acid, particularly nitric acid, at a temperature of 20 to 40° C. Preferably, a nitric acid solution in water with a concentration of 50 to 60 wt % nitric acid (with respect to the total weight of the solution) is used. Following this etching protocol excellently prepares the substrate for the coating step to apply the intermediate layer, such that a good adhesion can be obtained. After the two-step etching process, the roughness value R_{z} of the etched surface of the substrate can range from 0.1 to 2 μm. R_{z} can be calculated using the software of the optical microscope Keyence VHX-7000 (Keyence International, Belgium) by averaging the five highest peaks and the five deepest valleys within a predetermined measurement length. Further, the average roughness Rₐ of the etched surface of the substrate can range from 0.1 to 0.5 μm. In the present application, the roughness values were determined with the optical microscope Keyence VHX-7000 according to DIN EN ISO 4287 over a measurement length of 800 μm. It is noted that the exact roughness values depend i.a. on the roughness of the substrate surface obtained after grinding. When using tungsten carbide (WC) with a binder phase (particularly cobalt) as substrate, the R_{z} value can be in the range of half the size of the size of WC grains (which grain size can range from 0.2 μm to 5 μm, or even from below 0.2 μm to above 5 μm).

According to the present invention, the step of roughening the surface of the substrate with an etchant can be followed by a cleaning step of the substrate. The cleaning can be carried out with water. This serves to remove residues of the etchant and residues of the etched substrate (such as residues of the binder phase when using cemented carbide as substrate). Preferably, the surface of the substrate is dipped into a water bath, e.g. for up to 10 sec or up to 20 sec. The dipping can be followed by immersion for 1 to 5 min into an ultrasonic bath filled with water to yield a clean substrate surface free of any residues. Demineralized or deionized water is preferably used to clean the surface of the substrate, such that any contamination with ions otherwise present in water can be avoided. Such an ionic contamination could negatively impact the subsequent coating step, particularly the adhesion of the substrate surface to the subsequently applied intermediate layer. For example, the cleaning can be considered to be sufficient when the electrical conductivity of an ultrasonic bath filled with demineralized water is reduced to below 1 μS/cm, as measured with the Water Purity Tester HI98309 (Hanna Instruments, Graz, Austria).

The roughened surface of the substrate according to the present invention is subsequently coated with the intermediate layer. The intermediate layer can be coated onto the surface of the substrate by means of various thin film deposition processes like physical vapor deposition (PVD), chemical vapor deposition (CVD), atomic layer deposition (ALD) or sol-gel process. Preferably, the surface of the substrate is coated by means of plasma-enhanced atomic layer deposition (PE-ALD) or physical vapor deposition (PVD), as excellent results can be achieved herewith. For example, a uniform intermediate layer can be formed, which preferably is free of any holes or defects. The intermediate layer can comprise either a single layer or multiple layers, such as two, three or more layers. Using a multilayer set-up is advantageous in that a material having a high bond strength to the substrate can be selected as inner layer and a material having a high bond strength to diamond can be selected as outer layer. For example, the intermediate layer can comprise two layers, with one intermediate layer comprising Al₂O₃ and the other intermediate layer comprising AlCrXN, preferably AlCrSiN or AlCrBN.

It is preferred in the present invention that the intermediate layer has an average thickness in the range of 0.1 to 5 μm. Providing an average thickness of below 0.1 μm does not significantly improve the bonding strength and may even result in a layer with pinholes, whilst an intermediate layer with an average thickness of above 5 μm negatively impacts the bonding strength and residual stress. The thickness values of layers (intermediate layer, diamond layer) given in the present application were determined from scanning electron microscopy (SEM) images obtained from cross-sections of substrates coated with these layers. Average thickness values were calculated from three single measurements.

In a preferred embodiment according to the present invention, the roughened surface of the substrate is coated with an intermediate layer consisting of AlCrXN by means of arc PVD. The arc PVD process can utilize a standard direct current (DC)-arc evaporation with a steered arc set-up by means of an electromagnetic or permanent magnetic field. A multi arc-source set-up can be used, e.g. by using two or three arcs. The intermediate layer can be applied with a bias voltage to generate an electrical field in order to control the energy of the ions, such that the ions can reach the substrate surface onto which the intermediate layer is intended to be coated. An AlₐCr_{b}X_{c} target can be used to form the AlCrXN intermediate layer, with a being from 50 to 80 at %, b being from 20 to 50 at % and c being from 1 to 10 at %. The substrate temperature can be in the range of 400 to 500° C. and can be maintained by means of one or more radiant heaters. The pressure during the coating process can be in the range of 5·10⁻³ to 8·10⁻² mbar. Using an arc PVD process brings the advantage that the intermediate layer can be shot with ions during the coating process by means of a conventionally applied substrate bias, leading to an improved compression strength of the intermediate layer. After applying the arc PVD process, a surface of the formed intermediate layer can exhibit droplets and an increased roughness. Accordingly, the surface of the intermediate layer can be smoothened by different surface finishing methods, e.g. wet- or dry-blasting, brushing, lapping or by means of a drag and stream finishing process. In a preferred embodiment according to the present invention, the intermediate layer can be smoothend with a drag and stream finishing process well known in the art. The coated substrate can be clamped in a rotating holder and subsequently be submerged into a dry abrasive medium whilst being rotated. Said abrasive medium can comprise one or more abrasive particles, such as corundum particles, SiC particles, SiO₂ particles, walnut shell particles, diamond particles, or a mixture of walnut shell particles and diamond particles. The diameter of the particles of the abrasive medium can typically range from 0.2 to 10 mm. This allows for a reduction or even complete removal of droplets present onto the surface of the intermediate layer formed during the arc PVD process, which can excellently prepare the intermediate layer for the subsequent steps of the method according to the present invention. The resulting intermediate layer can have an average thickness in the range of 1 to 5 μm.

In a further preferred embodiment according to the present invention, the roughened surface of the substrate is coated with an intermediate layer consisting of Al₂O₃ by means of PE-ALD. This is a self-limited film growth method characterized by alternating exposure of a growing film to chemical precursors, resulting in a sequential deposition of (sub)monolayers. Key advantages of PE-ALD include a high film density, low impurity content, good stoichiometry and excellent electronic properties. Further, with PE-ALD, chemical reactions during the deposition of Al₂O₃ can be initiated already at a lower temperature in the range of 30 to 300° C. The temperature window can thus be extended downward. A plasma comprising 02, N₂, NH₃, H₂ or a mixture thereof can be used. As precursors to deposite Al₂O₃, trimethylaluminum (TMA) and oxygen (O₂) can be employed. The deposition can be performed with a pressure ranging from 10⁻¹ to 5 mbar. In contrary, under vacuum, the reaction of TMA and oxygen would be too slow to allow for a deposition within an economic period of time. A pulsed oxygen plasma with a high frequency (radio frequency (RF) of 13.56 MHz, up to very-high-frequency (VHF) of 60 MHz) can be applied. It can be sufficient to ignite the plasma only during an oxygen phase. Since oxygen does not react with TMA without excitation, time-consuming purging/pumping does not need to be carried out. Instead, the oxygen can be used directly as a purge gas. The resulting Al₂O₃ intermediate layer can have an average thickness in the range of 0.1 to 0.6 μm.

According to the present invention, a surface of the intermediate layer is nucleated. Said surface refers to the surface of the intermediate layer opposite to its surface facing the substrate. Nucleating this surface of the intermediate layer supports the growth of sp³-hybridized carbon when subsequently applying the diamond layer. Several nucleation processes can be used, such as (a) scratching the substrate, e.g. manually using a diamond paste or industrially via sand-blasting; (b) ultrasonic-seeding by a mixture of a solvent (e.g. isopropyl alcohol or demineralized water) and particles of a hard material (such as diamond particles or particles of Al₂O₃, SiC, BC, etc.); (c) bias-enhanced nucleation (BEN), hereby applying a negative potential to accelerate the charged species and bring them onto the substrate surface; (d) electro-spraying; or (e) dip-coating.

It is particularly preferred in the present invention that a high nucleation density of above 10¹⁰/cm² is achieved at the nucleated surface of the intermediate layer. The density can be determined by counting the seeds in images obtained from scanning electron microscopy (SEM) with an image processing software. This allows for a low roughness and excellent uniformity (e.g. significant reduction or even absence of holes and inhomogeneities) of the subsequently applied diamond layer. Further, owing to the good adhesion, a closed diamond layer can already be formed in an early stage of growth. Such a high nucleation density can for example be obtained with the following procedure: diamond particles with defined grain size (e.g. 5 to 10 nm) can be colloidally dissolved in a solvent. The use of isopropyl alcohol or demineralized water as solvent was shown to result in a good nucleation efficiency. The substrate coated with an intermediate layer can be nucleated in an ultrasonic bath for 10 min up to a few hours, depending on the concentration of the diamond particles (0.1 to 10 ct/liter) and the power of the ultrasonic device (100 to 1,000 W). Preferably, the nucleation time in the ultrasonic bath is from 10 to 30 min. Further preferably, the temperature in the ultrasonic bath can be in the range of 0° C. to 20° C. Using any of these parameters allows for an effective nucleation.

According to the present invention, a diamond layer is subsequently coated onto the nucleated surface of the intermediate layer by means of a CVD process. The diamond layer according to the present invention is intended to refer to either a microcrystalline or nanocrystalline diamond layer, or a combination of both (e.g. as multilayers or as a gradient layer). A hot-filament (HF−) CVD process can be used, as is commonly known in the art. Alternatively, the device and method disclosed in WO 2018/064694 A1 can be used to perform the CVD process of the present invention. The substrate comprising the intermediate layer can then be placed in a deposition chamber as substrate. A process gas (hydrogen or a mixture of hydrogen and a carbon-containing gas, e.g. methane) can be fed to a flow channel of a gas activation element by means of a gas inlet. A wall of the gas activation element that surrounds the flow channel can be heated, preferably at a temperature of at least 2,000° C., such that the process gas inside the flow channel can be thermally excited. The cross-sectional area of the flow channel preferably ranges from 5 to 30 mm² to increase the impact excitation of the process gas with the wall. Further preferably, the flow channel of the gas activation element is closed at both ends, e.g. with closing bodies, such that the gas activation element has no openings apart from an inlet opening and an outlet opening. The ratio between the area of exactly one outlet opening and the cross-sectional area of the gas activation element is preferably 1:5 to 1:20, in particular 1:10, which further enhances the excitation rate of the process gas. Due to the small number of openings and the flow channel closed at both ends, the partial pressure in the flow channel inside the gas activation element can increase significantly. As a result, the partial pressure can be up to several times higher than the pressure in the separation chamber. This allows to further excite the process gas by means of impact excitation (e.g. collision-induced dissociation) in addition to thermal excitation. Thus, preferably, the process gas comprising hydrogen is activated with a combination of thermal activation and impact excitation. This yields an excitation rate of atomic hydrogen of 80% and above, whilst thermal excitation alone can lead to an excitation rate of only up to 30%. This high excitation rate can accelerate diamond growth rates and can yield a diamond layer with a high purity. Further, owing to the high excitation rate and the controlled flow of the process gases in the present invention, it is possible to increase the distance of the gas activation element to the substrate, which significantly improves the homogeneity of the deposited diamond layer. In known hot filament CVD processes, a small distance of the gas activation element to the substrate (usually in the range of 5 to 10 mm) needs to be chosen due to the low excitation rate of the process gas which is led into the chamber in background without a local control. In contrary, in the CVD process according to WO 2018/064694 A1, it is possible to provide a larger distance between the gas activation element and the substrate surface owing to the comparatively high excitation rate of the process gas. The distance is preferably in the range of 20 to 100 mm, particularly preferably in the range of 40 to 60 mm, which ensures a homogeneous temperature distribution on the substrate surface, and consequently increases the homogeneity of the deposited diamond layer. During deposition of a diamond layer onto the surface of the substrate, the temperature of the substrate can range from 750 to 950° C. In the present invention, the substrate temperature preferably ranges from 750 to 850° C. The duration of the CVD process depends on the target thickness and is typically in the range of 10 h to 20 h. Further, the pressure in the deposition chamber can range from 1 to 40 mbar. Using any of these parameters helps to yield a homogeneous diamond layer.

With the method according to the present invention, an intermediate layer and a diamond layer nearly or even completely free of pinholes can be generated, such that a good interlayer-adhesion and a good adhesion to the substrate surface can be achieved. Further, during application of the diamond layer, the diffusion of atoms from the substrate, e.g. from its binder phase, towards the diamond layer can be reduced or even avoided. The formation of layers with few or no pinholes can be ensured in the present invention by a careful selection of processing parameters and optional cleaning steps in order to avoiding dust, contaminations or inclusions in the formed layers.

The present invention further relates to a substrate coated with an intermediate layer and a diamond layer obtainable by the inventive method. The intermediate layer is arranged between the substrate and the diamond layer.

According to a preferred embodiment of the present invention, the intermediate layer has an average thickness in the range of 1 to 5 μm, preferably 2 to 4 μm, and consists of AlCrSiN or AlCrBN. The intermediate layer can then be nearly or even completely pinhole-free, can compensate well for differences in thermal and/or mechanical stress between the substrate and the diamond layer, and has an excellent adhesion to both the substrate and the diamond layer. Further, if the substrate is a cemented carbide, said intermediate layer can provide an excellent diffusion barrier for the binder phase of the cemented carbide.

In an alternative preferred embodiment, the intermediate layer has an average thickness in the range of 0.1 to 0.6 μm, preferably 0.1 to 0.2 μm, and consists of aluminum oxide (Al₂O₃). The intermediate layer can then be nearly or even completely pinhole-free, can compensate well for differences in thermal and/or mechanical stress between the substrate and the diamond layer, and has an excellent adhesion to both the substrate and the diamond layer. Further, if the substrate is a cemented carbide, said intermediate layer can provide an excellent diffusion barrier for the binder phase of the cemented carbide.

Preferably, the diamond layer according to the present invention comprises at least 95 wt % of sp³-hybridized carbon (i.e. diamond), more preferably at least 98 wt/% of sp³-hybridized carbon, particularly preferably at least 99 wt % of sp³-hybridized carbon. This ensures a good quality of the diamond layer and an excellent adhesion to the intermediate layer. The average thickness of the diamond layer preferably ranges from 0.1 to 300 μm. An average thickness of below 0.1 μm is insufficient to provide a significant increase of the performance, such as wear resistance, whilst an average thickness of above 300 μm cannot yield a significant further improvement of properties.

Owing to the diamond layer, the coated substrate according to the present invention exhibits a high hardness and a high abrasion resistance. Thus, superior resistance to wear and fracture can be achieved along with a good adhesion and toughness, which in turn improves the durability.

Preferably, in the present invention, the area fraction of the binder phase of the substrate present in the intermediate layer is below 15%, more preferably below 12%, most preferably below 8%, with respect to the total area of the intermediate layer, as determined from a cross-section of the coated substrate via energy dispersive X-ray spectroscopy (EDX) analysis. Preferably, the substrate is a cemented carbide and the binder phase comprises cobalt or even consists of cobalt. The area fraction can be determined by subjecting the substrate coated with the intermediate layer to thermal treatment at 900° C. for 10 h under argon atmosphere (i.e. conditions typically applied during a CVD process), subsequently preparing a cross-section of the coated substrate and generating an EDX image. It is noted that the preferred temperature during the CVD process according to the present invention ranges from 750 to 850° C., however, using a higher temperature during thermal treatment can facilitate the evaluation of the diffusion characteristics of the intermediate layer. When subjecting the coated substrate to said thermal treatment, a diamond layer is not applied prior to EDX analysis. The area fraction can, however, also be determined from a cross-section of a substrate coated with the intermediate layer and the diamond layer, in which case the thermal treatment as described above is replaced by the CVD process. When conducting the CVD process at a temperature of 850° C. for 10 h, the obtained results correspond to those obtained when subjecting a substrate coated with an intermediate layer (and without a diamond layer) to thermal treatment. Owing to the low diffusion, the intermediate layer according to the present invention can act as an excellent diffusion barrier, which significantly reduces or even completely prevents diffusion of the binder phase in a cemented carbide towards and through the intermediate layer. The adhesion of the diamond layer to the intermediate layer can thus be significantly improved. Accordingly, a high-quality diamond layer can be deposited. It was found that with an intermediate layer consisting of AlCrSiN, AlCrBN or Al₂O₃, a particularly low diffusion of the binder phase, particularly cobalt, can be obtained. In contrary, when using an intermediate layer different to that of the present invention, the area fraction of the binder phase present in the intermediate layer can be significantly higher, e.g. above 15% or even above 20%, with respect to the total area of the intermediate layer. This in turn can deteriorate adhesion and thus impede the quality of the diamond layer.

According to the present invention, it is preferred that the roughness of the nucleated surface of the intermediate layer is in the same range as the surface of the etched substrate. Preferably, the roughness R_{z} of the nucleated surface of the intermediate layer ranges from 0.1 to 2 μm, particularly preferably from 0.2 to 2 μm, as determined with the optical microscope Keyence VHX-7000 according to DIN EN ISO 4287.

When using tungsten carbide (WC) with a binder phase (particularly cobalt) as substrate, it is preferred that the roughness of the cemented carbide is in the range of half of the size of WC grains (which grain size can range from 0.2 μm to 5 μm, or even from below 0.2 μm to above 5 μm). When applying an intermediate layer consisting of Al₂O₃, its surface can exhibit a roughness similar to the roughness of the surface of the etched substrate, owing to the small average thickness of the Al₂O₃, layer (e.g. below 0.2 μm). In contrary, when applying an intermediate layer consisting of AlCrSiN or AlCrBN, a lower roughness is obtained compared to the surface of the underlying substrate, due to the comparably higher average thickness of the AlCrSiN or AlCrBN layer (e.g. 2 to 4 μm).

The present invention is further explained below with reference to examples and descriptions of figures.

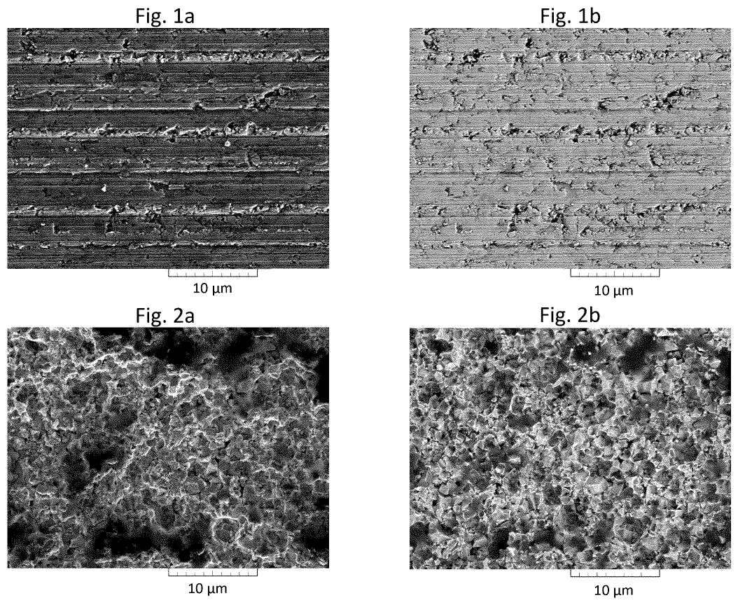

FIG. 1a-b show SEM images (taken with Tescan Mira, Tesca GmbH, Germany) of a ground surface of a cemented carbide substrate (magnification: 10,000). FIG. 1a displays a secondary electron (SE) image and FIG. 1b a backscattering electron (BSE) image. As can be seen, a cobalt binder phase of the substrate is smeared out on the surface after grinding (i.e., prior to etching).

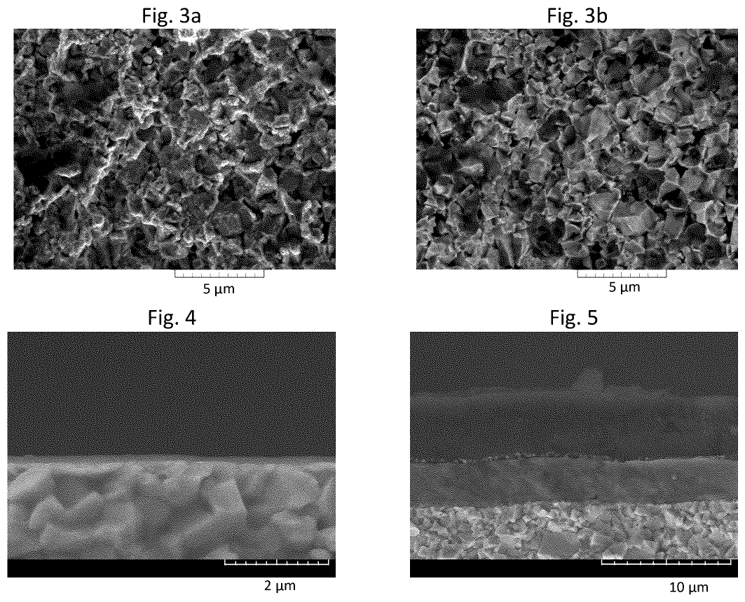

FIG. 2a-b and FIG. 3a-b display SEM images (taken with Tescan Mira) of a surface of the cemented carbide substrate shown in FIG. 1a-b after roughening with a two-step etching procedure (using a Murakami reagent and nitric acid). FIG. 2a and FIG. 3a display SE images whilst FIG. 2b and FIG. 3b display BSE images. The magnification is 10,000 in FIGS. 2a-b and 20,000 in FIG. 3a-b.

FIG. 4 displays a SEM image (taken with Hitachi SU-8010, Hitachi High-Technologies Corp., Japan) of a breaking edge of a substrate comprising tungsten carbide as hard phase and cobalt as binder phase, and coated with an Al₂O₃ layer (average thickness of 0.2 μm).

FIG. 5 shows a SEM image (taken with Hitachi SU-8010) of a breaking edge of a substrate comprising tungsten carbide as hard phase and cobalt as binder phase, and coated with an AlCrSiN layer (average thickness of 4 μm) and a diamond layer (average thickness of 6 μm).

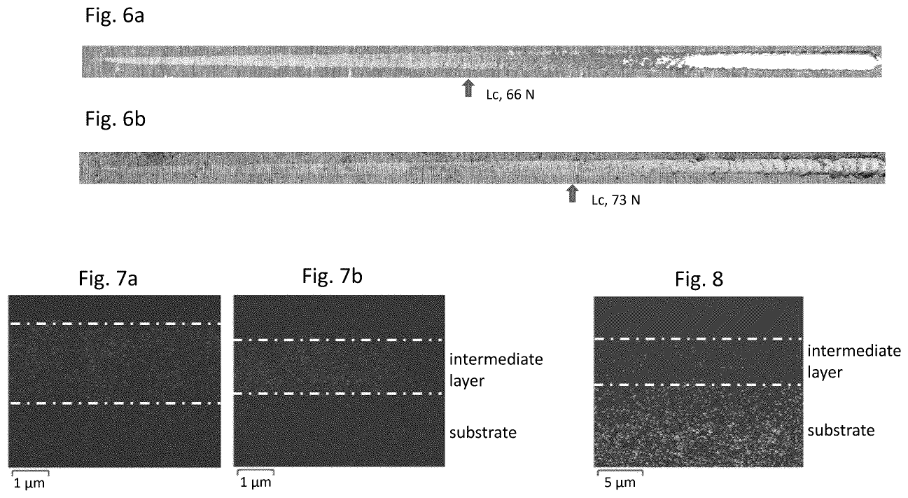

In FIG. 6a-b, results from scratch tests performed with substrates comprising tungsten carbide as hard phase and cobalt as binder phase, and coated with an intermediate layer (Al₂O₃ in FIG. 6a and AlCrSiN in FIG. 6b) and a diamond layer are shown.

FIG. 7a-b show EDX images of cross-sections of substrates coated with a reference intermediate layer, revealing a significant cobalt diffusion through the intermediate layer after thermally treating the coated substrate at 900° C. for 10 h under argon atmosphere in a vacuum furnace (DSVF-3, Daeheung Science Co., South Korea). In FIG. 7a, a-C:H:Si (average thickness of 2 μm) is used as intermediate layer, whilst in FIG. 7b, a-C:H:N (average thickness of 1.5 μm) is applied.

FIG. 8 shows an EDX image of a cross-section of a substrate coated with an AlCrSiN intermediate layer (average thickness of 4 μm) according to the present invention, revealing a comparably low cobalt diffusion after thermally treating the coated substrate at 900° C. for 10 h under argon atmosphere in a vacuum furnace (DSVF-3, Daeheung Science Co.).

### EXAMPLES

### Example 1—Preparation of Substrates Coated with an Intermediate Layer and a Diamond Layer According to the Present Invention

Substrates comprising tungsten carbide (WC) as hard phase and cobalt as binder phase (WC grain size of 0.7 to 1.2 μm and Co content of 6 to 10 wt %), and with a diameter of 6 mm and a length of 50 mm were cleaned by means of a standard cleaning process to remove lubricants and oil residues. A two-step etching process in an ultrasonic bath with a Murakami reagent and subsequently with nitric acid (53 wt %) was applied to roughen the surface of the substrates until an average R_{z} value of maximum half of the size of WC grains was obtained after etching. The surface of the substrate was etched with the Murakami reagent for 180 sec at 25° C. and with nitric acid for 60 sec at 25° C. Subsequently, a roughness profile of the substrate surface was measured with the optical microscope Keyence VHX-7000 according to DIN EN ISO 4287 over a length of 800 μm. The resulting roughness values R_{z} and Rₐ were calculated by Keyence Software from the obtained roughness profiles and amount to 0.98 μm and 0.14 μm, respectively. Subsequently, the etched surfaces of the substrates were coated with amorphous Al₂O₃ and AlCrSiN as intermediate layers, respectively.

(a) Amorphous Al₂O₃ as Intermediate Layer

An amorphous aluminum oxide (Al₂O₃) layer was deposited onto the surface of the roughened substrate over a coating length of 30 mm by means of PE-ALD. An Al₂O₃ layer with an average thickness of 0.2 μm was obtained, covering the entire surface area of the substrate. An established PE-ALD process was applied using two precursors, trimethylaluminum (TMA) and oxygen (O₂), under pre-vacuum in the pressure range from 10⁻¹ to 5 mbar. An oxygen plasma was ignited by a high frequency (13.56 MHz) at a process temperature below 100° C. A SEM image of a breaking edge of the substrate coated with the Al₂O₃ layer is shown in FIG. 4.

A surface of the Al₂O₃ layer was then nucleated in an ultrasonic bath filled with a diamond suspension (0.25 g suspended in 900 ml isopropyl alcohol) for 10 min at 0° C. and 300 W. Subsequently, a nanocrystalline diamond layer with an average thickness of 6 μm was coated onto the nucleated surface of the Al₂O₃ layer in a CVD process with the device described in WO 2018/064694 A1 using the process gases hydrogen 5.0 and methane 3.5. The process was carried out at a temperature ranging from 800 to 850° C. and a pressure of 10 mbar.

### (B) AlCrSiN as Intermediate Layer

An AlCrSiN layer was deposited onto the surface of the roughened substrate over a coating length of 35 mm by means of arc PVD at a temperature of 400 to 500° C. and a pressure of 5·10⁻³ to 8·10⁻² mbar. An AlₐCr_{b}X_{c} target with a of 60 at %, b of 30 at % and c of 10 at % was used. The resulting AlCrSiN layer had an average thickness of 4 μm and homogeneously covered the entire surface area of the substrate. The surface of the obtained intermediate layer was then smoothened by means of a drag and stream finishing process.

Subsequently, a surface of the AlCrSiN layer was nucleated in an ultrasonic bath filled with a diamond suspension (0.25 g dissolved in 900 ml isopropyl alcohol) for 10 min at 0° C. and 300 W. Subsequently, a nanocrystalline diamond layer with an average grain size of 5 to 15 nm and an average thickness of 6 μm was coated onto the nucleated surface of the AlCrSiN layer in a CVD process with the device described in WO 2018/064694 A1 using the process gases hydrogen 5.0 and methane 3.5. The process was carried out at a temperature ranging from 800 to 850° C. and a pressure of 10 mbar. FIG. 5 shows a SEM image of a breaking edge of the substrate coated with the AlCrSiN layer and the diamond layer.

### Example 2—Adhesion Tests

An adhesion test of the substrates coated with an intermediate layer (Al₂O₃ or AlCrSiN) and a diamond layer as prepared in Example 1 was performed by dry blasting with corundum particles (F90, 125 to 180 μm) at 3 bar. Both intermediate layers showed a good adhesion to the substrate, without any delamination or damage of the intermediate layer occurring for up to 30 sec for AlCrSiN and more than 120 sec for Al₂O₃.

### Example 3—Scratch Tests

The substrates coated with an intermediate layer (Al₂O₃ or AlCrSiN) and a diamond layer as prepared in Example 1 were further subjected to a scratch test. The scratch test was performed with an automated Revetest® Scratch Tester RST³ (Anton Paar, Austria) complying with ASTM C1624, ISO 20502 and ISO EN 1071. This scratch tester is widely used for characterizing hard-coated materials with a typical coating thickness exceeding 1 μm. The following parameters were used: Diamond Rockwell indenter with 200 μm radius, progressive load scratch mode, scratch length 2 mm, scratch load 0.5 to 60 N, loading rate 300 N/min. The critical load (Lc) was 66 N for the substrate coated with Al₂O₃ as intermediate layer (see FIG. 6a), and 73 N for the substrate coated with AlCrSiN as intermediate layer (see FIG. 6b).

### Example 4—Diffusion of Cobalt Through Intermediate Layer

The diffusion of cobalt present as binder phase in a tungsten carbide substrate through various intermediate layers was analyzed by means of energy dispersive X-ray spectroscopy (EDX) analysis. Substrates, each coated with a different intermediate layer, were subjected to thermal treatment for 10 h at 900° C. under argon atmosphere in a vacuum furnace (DSVF-3, Daeheung Science Co.). After the thermal treatment, cross-sections of the coated substrates were prepared to be subjected to EDX analysis, which was performed with the field emission scanning electron microscope Hitachi SU8010 and the EDX device Horiba X-Max N50 (Horiba Ltd., Japan). The cross-sections of the coated substrates were loaded into a vacuum chamber via a sub-chamber. The measurements were carried out at room temperature (20 to 25° C.), the pressure in the vacuum chamber was in the range of 10⁻⁴ to 10⁻³ Pa, the voltage and current were 10 kV and 10 μA, respectively. Images were taken with 300,000 counts/image, a process time of 4 sec and a pixel dwell time of 10 ms, and 1024 channels. The EDX device was operated in cold type and a working distance of 15 mm was applied.

Substrates coated with an intermediate layer were prepared following the preparation method disclosed in Example 1. The following systems are examples of a variety of the tested intermediate layer (average thickness and coating method in brackets): SiO₂, (1 μm; PE-CVD), a-C:H:Si (2 μm; PE-CVD), a-C:H:N (1.5 μm; PE-CVD), AlTiN (1 μm, 2 μm; arc PVD), AlTiSiN (1 μm, 2 μm; arc PVD), AlCrN (1 μm, 2 μm; arc PVD), AlCrSiN, using various targets with a Si content in the range of 1 to 10 at %) (1 μm, 2 μm, 4 μm; arc PVD), Al₂O₃ (0.2 μm; PE-ALD); Cr (1 μm; arc PVD) and Ti (1 μm; arc PVD).

The EDX analysis confirmed a significant cobalt diffusion from the substrate into and through most of the analyzed intermediate layers, towards the surface of the intermediate layer opposite its surface facing the substrate. The area fraction of cobalt present in the intermediate layer after the thermal treatment was calculated from EDX images of the cross-sections with a conventional image processing software. Exemplary EDX images of cross-sections of substrates coated with an a-C:H:Si intermediate layer (average thickness of 2 μm) and with an a-C:H:N intermediate layer (average thickness of 1.5 μm) are shown in FIG. 7a and FIG. 7b, respectively. The area fraction of cobalt present in the intermediate layer after thermal treatment was 19% for the substrate coated with a-C:H:Si, and 23% for the substrate coated with a-C:H:N (each with respect to the total area of the intermediate layer). In contrary, when coating the substrate with an inventive intermediate layer consisting of AlCrSiN or Al₂O₃, respectively, the EDX analysis surprisingly revealed a significant reduction of the diffusion of cobalt into and through each of these two intermediate layers. An exemplary EDX image of a cross-section of a substrate coated with an AlCrSiN intermediate layer (average thickness of 4 μm) is displayed in FIG. 8. The area fraction of cobalt present in the AlCrSiN layer after thermal treatment was only 6% (with respect to the total area of the intermediate layer), which confirms the excellent ability of the inventive intermediate layer to act as cobalt passivation layer.

### Example 5—Performance Tests of Carbide Tools Coated with an Intermediate Layer and a Diamond Layer

Carbide router end mills with a diameter of 10 mm comprising tungsten carbide (WC) as hard metal (WC grains with a size of 1 μm) and cobalt (Co) as binder phase (Co content of 6 wt %) were coated with an intermediate layer and a nanocrystalline diamond layer (average thickness of 6 μm) following the preparation method of Example 1. An Al₂O₃ layer (average thickness of 0.2 μm) was applied by means of PE-ALD, whilst an AlCrSiN layer (average thickness of 4 μm) was applied by means of arc PVD. Further, a carbide router end mill was wet-etched to remove cobalt and then coated with a diamond layer as reference (i.e., no intermediate layer was applied). The average thickness of the nanocrystalline diamond layer was 6 μm for all prepared carbide router end mills. The wear was measured with a mean wear width mark after a milling path of 36 m of machining of a highly abrasive carbon fiber-reinforced polymer (CFRP; carbon fibers of type T700 with a tow size of 12 k).

The results revealed a significantly superior performance when using a carbide router end mill coated with an intermediate layer and a diamond layer according to the present invention. Namely, an average wear of only 118 μm and 65 μm was achieved when using Al₂O₃ and AlCrSiN as intermediate layer, respectively. In contrary, when wet-etching the substrate and immediately applying a diamond layer, a significantly higher average wear of 174 μm was obtained.

1. A method for preparing a substrate coated with an intermediate layer and a diamond layer, comprising the following steps:
(a) roughening a surface of the substrate with an etchant,
(b) coating the roughened surface of the substrate with an intermediate layer,
(c) nucleating a surface of the intermediate layer, and
(d) coating the nucleated surface of the intermediate layer with a diamond layer by means of a chemical vapor deposition (CVD) process,
wherein the intermediate layer comprises aluminum oxide (Al₂O₃) and/or AlCrXN, with Al being aluminum, Cr being chromium, X being a metalloid, and N being nitrogen.

2. The method according to claim 1, wherein the substrate is a cemented carbide.

3. The method according to claim 1, wherein the intermediate layer consists of AlCrSiN, AlCrBN or Al₂O₃.

4. The method according to claim 1, wherein the Al₂O₃ is amorphous.

5. The method according to claim 1, wherein the surface of the substrate is etched with a Murakami reagent.

6. The method according to claim 5, wherein the surface of the substrate is etched in a two-step etching process by etching with a Murakami reagent and an acid.

7. The method according to claim 6, wherein the surface of the substrate is etched for 30 sec to 5 min with the Murakami reagent and 30 sec to 5 min with nitric acid, at a temperature of 20° C. to 40° C.

8. The method according to claim 1, wherein the surface of the substrate is coated with an intermediate layer consisting of AlCrXN by means of arc physical vapor deposition (PVD).

9. The method according to claim 1, wherein the surface of the substrate is coated with an intermediate layer consisting of Al₂O₃ by means of plasma-enhanced atomic layer deposition (PE-ALD).

10. The method according to claim 1, wherein a process gas comprising hydrogen is activated with a combination of thermal activation and impact excitation in the CVD process.

11. A substrate coated with an intermediate layer and a diamond layer obtainable by the method according to claim 1.

12. The substrate according to claim 11, wherein the intermediate layer has an average thickness in the range of 1 to 5 μm and consists of AlCrSiN or AlCrBN.

13. The substrate according to claim 11, wherein the intermediate layer has an average thickness in the range of 0.1 to 0.6 μm and consists of aluminum oxide (Al₂O₃).

14. The substrate according to claim 11, wherein the area fraction of a binder phase of the substrate present in the intermediate layer is below 15% with respect to the total area of the intermediate layer, as determined from a cross-section of the coated substrate via energy dispersive X-ray spectroscopy (EDX) analysis according to the description.

15. The substrate according to claim 11, wherein the nucleated surface of the intermediate layer has a roughness R_{z} in the range of 0.1 μm to 2 μm, as determined according to the description.

16. The method of claim 1, wherein X is silicon (Si) or boron (B).

17. The method of claim 6, wherein the acid is nitric acid.
